(19) United States
(12) Patent Application Publication
(10) Pub. No.: US 2024/0177992 A1
(43) Pub. Date: May 30, 2024

(54) METHOD OF FORMING AN ORGANIC POLYMER COMPRISING POLYIMIDE

(71) Applicant: ASM IP Holding B.V., Almere (NL)

(72) Inventors: Andrea Illiberi, Leuven (BE); Shaoren Deng, Ghent (BE); Giuseppe Alessio Verni, Vantaa (FI); Daria Nevstrueva, Helsinki (FI); Marko Tuominen, Helsinki (FI); Charles Dezelah, Helsinki (FI); Daniele Chiappe, Munich (DE); Eva Elisabeth Tois, Espoo (FI); Viraj Madhiwala, Heverlee (BE); Michael Givens, Oud-Heverlee (BE)

(21) Appl. No.: 18/519,172

(22) Filed: Nov. 27, 2023

Related U.S. Application Data
(60) Provisional application No. 63/428,763, filed on Nov. 30, 2022.

(51) Int. Cl. H01L 21/02

(52) U.S. Cl. CPC H01L 21/02337; H01L 21/02118; H01L 21/02205; H01L 21/0228

(57) ABSTRACT

The disclosure relates to methods of forming organic polymers comprising polyimide and layers comprising the same and to methods of reducing polyamic acid content of an organic polymer. The embodiments of the disclosure further relate to methods of fabricating semiconductor devices, to selectively depositing a material on a surface of a semiconductor substrate and to semiconductor processing assemblies. The methods are characterized by contacting a polyimide-containing material, such as a layer, with a modifying agent that increases the proportion of polyimide in the organic polymer material.

### CROSS-REFERENCE TO RELATED APPLICATIONS

This application claims priority to and the benefit of U.S. Provisional Application No. 63/428,763, filed Nov. 30, 2022, the entirety of which is incorporated by reference herein.

### FIELD OF INVENTION

The present disclosure relates to methods and apparatuses for the deposition of organic material on a substrate. In aspects, the disclosure relates to methods and apparatuses for manufacturing semiconductor devices and organic layers of specific material composition.

### BACKGROUND OF THE DISCLOSURE

Organic thin films have valuable optical, thermal, electrical and mechanical properties and are widely used in the electronics, medical engineering, defense, pharmaceutical, and micro- and nanotechnology industries. Polymers in the microelectronics and photonics industries include, among other examples, photon- or electroncurable/degradable polymers for lithographic patterning; and polyimides for packaging, interlayer dielectrics and flexible circuit boards.

Organic polymer layers can be used, for example, as a starting point in semiconductor applications. Especially, layers comprising polyimide are valuable for their thermal stability and resistance to mechanical stress and chemicals. For example, layers comprising polyimide can be used as antireflection layers to improve pattern definition and reduce misalignment in lithography steps, as layers in multiple patterning, as insulating materials for interlayer dielectric materials, as the gate dielectric in all-organic thin film transistors, as passivation films in packaging applications, etc. Similarly, polyamide and other organic films are valuable for their electrical properties and material properties for numerous applications. Polyamide films may be used, for example, as insulating materials for interlayer dielectric materials in integrated circuit fabrication, and the photosensitivity of polyamide through ultraviolet (UV) curing allows patterning without separate photoresist.

As semiconductor chip sizes continue to shrink, thinner and higher-strength films with more tunable morphology and composition are required. Vapor phase deposition processes such as chemical vapor deposition (CVD), vapor deposition polymerization (VDP), molecular layer deposition (MILD), and sequential deposition processes such as atomic layer deposition (ALD) and cyclical CVD have been applied to the formation of polymer thin films. In some applications, organic polymer layers are selectively deposited on predetermined areas of a substrate relative to other areas of the same substrate. However, the composition of the organic polymer material may in part depend on the surface on which it is deposited. Such substrate effects may be more pronounced the thinner the deposited organic polymer layer is. Such thinner layers, in turn, are becoming increasingly important as the manufacture of electronic devices becomes ever more sophisticated.

Thus there is need in the art for improved control of the composition of the deposited organic polymer material.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of forming modified organic polymers comprising polyimide and layers comprising the same and to methods of reducing polyamic acid content of an organic polymer. The embodiments of the disclosure further relate to methods of fabricating semiconductor devices, to selectively depositing a material on a surface of a semiconductor substrate and to semiconductor processing assemblies.

In one aspect, a method of forming a modified organic polymer comprising polyimide is disclosed. The method comprises providing a substrate in a reaction chamber, providing a first polymer precursor into the reaction chamber in a vapor phase and providing a second polymer precursor into the reaction chamber in a vapor phase to deposit an organic polymer comprising polyimide on the substrate. The first polymer precursor comprises a molecule having at least two acid anhydride groups and the second polymer precursor comprises a molecule comprising at least two amine groups. The method further comprises providing a modifying agent into the reaction chamber in a vapor phase to increase the proportion of polyimide in the organic polymer on the substrate to form the modified organic polymer comprising polyimide.

In some embodiments, providing a first polymer precursor and providing the second polymer precursor into the reaction chamber are repeated at least once. In some embodiments, providing the first polymer precursor and the second polymer precursor into the reaction chamber are repeated at least once before providing the modifying agent into the reaction chamber.

In some embodiments, the molecule comprising at least two acid anhydride groups is pyromellitic dianhydride.

In some embodiments, the molecule comprising at least two amine groups comprises at least one primary amine. In some embodiments, the molecule comprising at least two amine groups is selected from a group consisting of 4,4′-oxydianiline or 1,4-diaminobenzene, 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine, 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 1,6-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene, 1,4-diaminobenzene, 1,4-diaminobenzene and decane-1,10-diamine, 4-nitrobenzene-1,3-diamine.

In some embodiments, the modifying agent is a dehydrating agent. In some embodiments, the modifying agent is selected from a group consisting of carboxylic acids, acid anhydrides and primary amines. In some embodiments, the modifying agent comprises an aromatic ring. In some embodiments, the modifying agent is selected from a group consisting of acetic acid, formic acid, benzoic acid, m-hydroxybenzoic acid, p-hydroxybenzoic acid, p-aminobenzoic acid, m-aminobenzoic acid, benzene-1,4-dicarboxylic acid, acetic anhydride, succinic anhydride, maleic anhydride, phthalic anhydride, aniline, 4-aminophenol and quinolone.

In some embodiments, the method according to the current disclosure is a cyclic deposition method and comprises providing the first polymer precursor and the second polymer precursor into the reaction chamber alternately and sequentially. In some embodiments, the method is a cyclic deposition method and comprises providing the first polymer precursor and the second polymer precursor into the reaction chamber at least twice before providing the modifying agent into the reaction chamber. In some embodiments, the first polymer precursor and the second polymer precursor are provided into the reaction chamber at least five times before providing the modifying agent into the reaction chamber. In some embodiments, the first polymer precursor and the second polymer precursor are provided into the reaction chamber at most five times before providing the modifying agent into the reaction chamber.

In some embodiments, the temperature of the reaction chamber during providing the modifying agent into the reaction chamber is from about 200° C. to about 450° C. In some embodiments, the pressure of the reaction chamber is between about 2 Torr and about 8 Torr during providing the modifying agent into the reaction chamber.

In some embodiments, the ratio of polyamic acid to polyimide in the organic polymer is reduced from at least about 3:1 to about 1:1. In some embodiments, the ratio of polyamic acid to polyimide in the organic polymer is reduced from at least about 3:1 to about 1:30 or less. In some embodiments, the organic polymer comprising polyimide formed according to the current disclosure (i.e. after treatment by modifying agent) has a ratio of polyamic acid to polyimide of about 1:10 or less. In some embodiments, the modified organic polymer comprising polyimide formed according to the current disclosure has a ratio of polyamic acid to polyimide of about 1:20 or less. In some embodiments, the modified organic polymer comprising polyimide formed according to the current disclosure has a ratio of polyamic acid to polyimide of about 1:30 or less, or about 1:40 or less. For example, the ratio of polyamic acid to polyimide in a modified organic polymer formed by methods disclosed herein may be about 1:50. In some embodiments, polyamic acid is substantially removed from the modified organic polymer comprising polyimide. The analysis of material properties may be challenging, since the as-deposited organic polymer and the modified organic polymer formed through the exposure to modifying agent are chemically similar. The ratio of polyamic acid to polyimide was evaluated by comparing signal strength in FTIR measurement.

In one aspect, a modified organic polymer layer comprising polyimide produced by the methods according to the current disclosure is disclosed. In some embodiments, the modified organic polymer layer according to the current disclosure is substantially polyamic acid-free.

In another aspect, a method of reducing polyamic acid content of an organic polymer comprising polyimide and polyamic acid is disclosed. The method comprises heating an as-deposited organic polymer to a temperature of at least about 170° C.; and contacting the as-deposited organic polymer with a vapor-phase modifying agent comprising a hydroxyl group or a carbonyl group to imidize polyamic acid into polyimide. In some embodiments, the temperature during contacting the organic polymer comprising polyimide is at most about 350° C. In some embodiments, the as-deposited organic polymer is a vapor-deposited layer on a semiconductor substrate.

In a further aspect, a method of forming a layer of modified organic polymer comprising polyimide on a surface of a semiconductor substrate is disclosed. The method comprises providing the semiconductor substrate in a reaction chamber, providing a first polymer precursor into the reaction chamber in a vapor phase, providing a second polymer precursor into the reaction chamber in a vapor phase to deposit an organic polymer comprising polyimide on the substrate. The first polymer precursor comprises a molecule having at least two acid anhydride groups and the second polymer precursor comprises a molecule comprising at least two amine groups. The method further comprises providing a modifying agent into the reaction chamber in a vapor phase to increase the proportion of polyimide in the organic polymer formed on the substrate.

In a yet another aspect, method of fabricating a semiconductor device is disclosed. The method comprises forming a layer of modified organic polymer comprising polyimide on a surface of a semiconductor substrate according to the current disclosure.

In a yet another aspect, a method of selectively depositing a material on a first surface of a semiconductor substrate relative to a second surface of the same substrate is disclosed. In the method, the first surface and the second surface have different material properties, and the second surface comprises a layer of modified organic polymer comprising polyimide formed according to the current disclosure.

In a yet further aspect, a semiconductor processing assembly for processing a substrate is disclosed. The processing assembly according to the current disclosure comprises a reaction chamber constructed and arranged to hold a substrate, a reactant source constructed and arranged to contain and evaporate a modifying agent comprising a carbonyl group or a hydroxyl group, a temperature control system constructed and arranged to regulate the temperature in the reaction chamber to be between 200° C. and 450° and a reactant injection system constructed and arranged to provide the modifying agent into the reaction chamber. In some embodiments, the semiconductor processing assembly further comprises a first polymer precursor source and a second polymer precursor source constructed and arranged to contain and evaporate a first polymer precursor and a second polymer precursor, respectively, and the reactant injector system is constructed and arranged to provide the first polymer precursor and the second polymer precursor into the reaction chamber to deposit an organic polymer comprising polyimide on the substrate.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1 is a block diagram of exemplary embodiments of a method according to the current disclosure.

FIG. 2 is a block diagram of further exemplary embodiments of a method according to the current disclosure.

FIG. 3 is a schematic drawing of an embodiment of a semiconductor processing assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, layers, and processing assemblies provided below is merely exemplary and is intended for purposes of illustration only. Although certain embodiments and examples are disclosed below, it will be understood by those in the art that the invention extends beyond the specifically disclosed embodiments and/or uses of the invention and obvious modifications and equivalents thereof. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

In an aspect, a method of forming modified organic polymer comprising polyimide is disclosed, wherein the method comprises providing a substrate in a reaction chamber, providing a first polymer precursor into the reaction chamber in a vapor phase, providing a second polymer precursor into the reaction chamber in a vapor phase to deposit an organic polymer comprising polyimide on the substrate. The first polymer precursor comprises a molecule having at least two acid anhydride groups and the second polymer precursor comprises a molecule comprising at least two amine groups and the method further comprises providing a modifying agent into the reaction chamber in a vapor phase to form a modified organic polymer comprising polyimide.

### Substrate

As used herein, the term “semiconductor substrate” may refer to any underlying material or materials that may be modified, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. A substrate according to the current disclosure comprises two surfaces having different material properties.

A “substrate” may also be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate or a semiconductor substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

### First Polymer Precursor and Second Polymer Precursor

In the methods of forming modified organic polymer comprising polyimide according to the current disclosure, a substrate, such as a semiconductor substrate, is provided in a reaction chamber. A first polymer precursor and a second polymer precursor are provided into the reaction chamber in a vapor phase.

The first polymer precursor comprises a molecule having at least two acid anhydride groups. In some embodiments, the first polymer precursor is a molecule having at least two acid anhydride groups. Thus, in some embodiments, the first polymer precursor is a dianhydride. In some embodiments, the molecule comprising at least two acid anhydride groups is pyromellitic dianhydride.

The second polymer precursor reacts with the first polymer precursor on the surface of the substrate to form as-deposited organic polymer comprising polyimide on the substrate. The second polymer precursor comprises a molecule comprising at least two amine groups. In some embodiments, the second polymer precursor is a molecule comprising at least two amine groups. In some embodiments, the molecule comprising at least two amine groups comprises at least one primary amine. In some embodiments, the molecule comprising at least two amine groups comprises two primary amines. In some embodiments, the molecule comprising at least two amine groups comprises three primary amines. In some embodiments, the molecule comprising at least two amine groups comprises four primary amines. In some embodiments, the second vapor phase precursor comprises a diamine.

In some embodiments, the diamine is a C2 to C15 compound. In some embodiments, the diamine is a C2 to C8 compound. In some embodiments, the diamine is a C2 to C6 compound. In some embodiments, the diamine is a C4 to C8 compound. In some embodiments, the diamine comprises a halogen. In some embodiments, the two amine groups are attached to different carbon atoms, and the two carbon atoms are non-adjacent.

In some embodiments, the molecule comprising at least two amine groups is selected from a group consisting of 4,4′-oxydianiline or 1,4-diaminobenzene, 2-diaminoethane, 1,3-diaminopropane, 1,4-diaminobutane, 1,5-diaminopentane, 1,2-diaminopropane, 2,3-butanediamine, 2,2-dimethyl-1,3-propanediamine, 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 1,6-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene, 1,4-diaminobenzene.

In some embodiments, the molecule comprising at least two amine groups is a cyclic compound. In some embodiments, the cyclic compound comprises an aromatic ring. In some embodiments, the cyclic compound does not comprise an aromatic ring. In some embodiments, the cyclic compound does not comprise p-phenylenediamine. In some embodiments, the cyclic compound comprises an alicyclic ring. In some embodiments, the cyclic compound comprises a six-membered carbocycle comprising two primary amine groups, bonded directly or indirectly to positions 1 and 4 of the carbon ring, respectively. In some embodiments, the cyclic compound comprises a six-membered carbocycle comprising two primary amine groups, bonded directly to positions 1 and 4 of the carbon ring, respectively. In some embodiments, the cyclic compound comprises a six-membered carbocycle comprising three primary amine groups, bonded directly or indirectly to positions 1, 3 and 5 of the carbon ring, respectively. In some embodiments, the cyclic compound comprises a six-membered carbocycle comprising three primary amine groups, bonded directly to positions 1, 3 and 5 of the carbon ring, respectively. In some embodiments, the cyclic compound comprises at least one of cyclopentanedialkanamine, cyclohexanedialkanamine, cyclopentadienedialkanamine, benzenedialkanamine, cyclopentanetrialkanamine, cyclohexanetrialkanamine, cyclopentadienetrialkanamine and benzenetrialkanamine. Each alkyl of said alkanamines may be independently selected from methyl, ethyl, propyl (including n-propyl and isopropyl) and butyl (including n-butyl, sec-butyl, isobutyl and tert-butyl).

In some embodiments, the non-aromatic cyclic diamine compound is a trans isomer of the compound. In some embodiments, the non-aromatic cyclic diamine compound is a cis isomer of the compound. In some embodiments, the non-aromatic cyclic diamine compound is a mixture of cis and trans isomers of the compound. Without limiting the current disclosure to any specific theory, trans isomers of the cyclic compounds may have more desired reactivity and usability in the processes according to the current disclosure.

In some embodiments, the cyclic compound is selected from a group consisting of 1,3-cyclopentanediamine, 3,5-cyclopentadiene-1,3-diamine, 2,4-cyclopentadiene-1,3-diamine, 1,3-cyclopentanedimethanamine, 3,5-cyclopentadiene-1,3-dimethanamine, 2,4-cyclopentadiene-1,3-dimethanamine, 1,4-diaminocyclohexane, 1,3-cyclohexanediamine, 1,2-cyclohexanediamine, 1,4-cyclohexanedimethanamine, 1,3-cyclohexanedimethanamine, 1,2-cyclohexanedimethanamine, 1,4-cyclohexanediethanamine, 1,3-cyclohexanediethanamine, 1,2-cyclohexanediethanamine, 1,2,3-cyclopentanetriamine, 1,2,4-cyclopentanetriamine, 1,3-cyclopentadiene-1,2,4-triamine, 1,2,3-cyclohexanetriamine, 1,2,4-cyclohexanetriamine, 1,3,5-cyclohexanetriamine, 1,3,5-cyclohexanetrimethanamine, p-phenylenediamine, m-phenylenediamine, o-phenylenediamine, 1,4-benzenedimethanamine, 1,3-benzenedimethanamine, 1,2-benzenedimethanamine, 1,2,3-benzenetriamine, 1,2,4-benzenetriamine, 1,3,5-benzenetriamine, 1,2,3-benzenetrimethanamine, 1,2,4-benzenetrimethanamine and 1,3,5-benzenetrimethanamine.

In some embodiments, the cyclic compound is selected from compounds having a cyclopentane, cyclopentadiene, cyclohexane or a benzene ring and two primary amine containing substituents, wherein the primary amine containing substituents are independently selected from —NH₂, —CH₂NH₂ and —CH₂CH₂NH₂. Thus, the substituents may be the same, such as both substituents are —NH₂, or both substituents are —CH₂NH₂ or both substituents are —CH₂CH₂NH₂. The substituents may be different. For example, one substituent may be —NH₂, and the second one —CH₂NH₂. One substituent may be —NH₂, and the second one —CH₂CH₂NH₂. One substituent may be —CH₂CH₂NH₂, and the second one —CH₂NH₂.

In some embodiments, the cyclic compound is selected from compounds having a cyclopentane, cyclopentadiene, cyclohexane or a benzene ring and three primary amine containing substituents, wherein the amine containing substituents are independently selected from —NH₂, —CH₂NH₂ and —CH₂CH₂NH₂. Thus, the substituents may be the same, such as all three substituents are —NH₂, or all three substituents are —CH₂NH₂ or all three substituents are —CH₂CH₂NH₂. The substituents may be different. For example, one substituent may be —NH₂, and the second one —CH₂NH₂ and the third one —CH₂CH₂NH₂. One substituent may be —NH₂, and the two other substituents —CH₂NH₂. One substituent may be —CH₂NH₂, and the two other substituents —NH₂. One substituent may be —NH₂, and the two other substituents —CH₂CH₂NH₂. One substituent may be —CH₂CH₂NH₂, and the two other substituents —NH₂. One substituent may be —CH₂NH₂, and the two other substituents —CH₂CH₂NH₂. One substituent may be —CH₂CH₂NH₂, and the two other substituents —CH₂NH₂.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

In some embodiments, a precursor is provided in a mixture of two or more compounds. In a mixture, the other compounds in addition to the precursor may be inert compounds or elements. In some embodiments, a precursor is substantially or completely formed of a single compound. In some embodiments, a precursor is provided in a composition. Composition may be a solid, a solution or a gas in standard conditions.

The terms first polymer precursor and second polymer precursor are used to denote different chemistries only, and the terms are to be understood as not relating to the order in which the polymer precursors are provided into the reaction chamber. In some embodiments, the second polymer precursor is provided into the reaction chamber first, and the first polymer precursor is provided into the reaction chamber after the second polymer precursor. This may be the case of cyclic and non-cyclic processes alike.

### Modifying Agent

The method according to the current disclosure comprises providing a modifying agent into the reaction chamber in a vapor phase. The modifying agent is provided into the reaction chamber to modify the as-deposited organic polymer comprising polyimide. In some embodiments, providing a modifying agent into the reaction chamber increases the proportion of polyimide in the as-deposited organic polymer on the substrate to form the modified organic polymer comprising polyimide. In some embodiments, providing a modifying agent into the reaction chamber improves the passivation properties of the as-deposited organic polymer comprising polyimide. For example, an organic polymer formed through the reaction of an amine and an acid anhydride may form imines and, if the precursors are selected suitably, a polymerized polyimide. However, without limiting the current disclosure to any specific theory, the reaction may not produce only polyimide, but a proportion of the polymer may be in the form of polyamic acid and/or polyamide. The properties of a polymer comprising significant proportion of polyamic acid differ from those of a polymer comprising mainly, substantially only, or only, of polyimide. In some embodiments, polyamide is formed to a lesser extent. Polyimide may have advantageous properties for semiconductor processing, such as for functioning as a passivation in area-selective deposition. Providing a modifying agent that is able to cause the imidization of polyamic acid into polyimide was found to improve the properties of the as-deposited organic polymer. The modifying agent is provided into the reaction chamber in vapor phase. In some embodiments, the modifying reactant is provided into the reaction chamber after the organic polymer comprising polyimide has been deposited.

In some embodiments, the modifying agent is a dehydrating agent. Dehydration may lead to not only the improvement of the organic polymer itself, but it may also avoid unwanted side reaction during further processing—such as selective deposition—of the substrate. In some embodiments, the modifying agent is selected from a group consisting of carboxylic acids, acid anhydrides and primary amines. In some embodiments, the modifying agent is a carboxylic acid. In some embodiments, the modifying agent is a dicarboxylic acid. Examples of suitable carboxylic acids are formic acid, acetic acid, benzoic acid, m-hydroxybenzoic acid, p-hydroxybenzoic acid, p-aminobenzoic acid, m-aminobenzoic acid and benzene-1,4-dicarboxylic acid.

In some embodiments, the modifying agent is an acid anhydride. Examples of an acid anhydrides are acetic anhydride, succinic anhydride, maleic anhydride and phthalic anhydride. In some embodiments, the modifying agent is an amine. In some embodiments, the amine is a primary amine. Examples of a primary amines are aniline, 4-aminophenol, p-aminobenzoic acid and m-aminobenzoic acid. In some embodiments, the amine is a secondary amine. An example of secondary amine is benzimidazole. In some embodiments, the modifying agent comprises an amide, specifically a lactam.

In some embodiments, the modifying agent comprises an aromatic ring. In some embodiments, the modifying agent is selected from a group consisting of acetic acid, formic acid, benzoic acid, m-hydroxybenzoic acid, p-hydroxybenzoic acid, p-aminobenzoic acid, m-aminobenzoic acid, benzene-1,4-dicarboxylic acid, acetic anhydride, aniline, 4-aminophenol and quinolone.

In some embodiments, the modifying agent may passivate the organic polymer. In other words, the modified organic polymer comprising polyimide is passivated organic polymer comprising polyimide. This may be effected through, for example, the incorporation of passive groups, such as aromatic rings, on the surface of the as-deposited organic polymer. For example, phthalic anhydride may react with available —NH₂ groups in or on the polymer to make them unavailable for further reaction. Similarly, aniline may be used to react with acid anhydride groups and provide an unreactive aryl ring in the structure.

In some embodiments, the modifying agent is the same as the first polymer precursor. In some embodiments, the modifying agent is the same as the second polymer precursor. In some embodiments, the modifying agent is different from the first polymer precursor and the second polymer precursor. In some embodiments, the first polymer precursor and the modifying agent are acid anhydrides. In some embodiments, the first polymer precursor is pyromellitic anhydride, and the modifying agent is a different acid anhydride. In some embodiments, the second polymer precursor and the modifying agent are primary amines. In some embodiments, the second polymer precursor is 1,6-diaminohexane and the modifying agent is a different primary amine. In some embodiments, the second polymer precursor is 1,6-diaminohexane and the modifying agent is an aromatic primary amine.

In some embodiments, the first polymer precursor is pyromellitic dianhydride, the second polymer precursor is 1,6-diaminohexane and the modifying agent is acetic anhydride. In some embodiments, the first polymer precursor is pyromellitic dianhydride, the second polymer precursor is 1,6-diaminohexane and the modifying agent is phthalic anhydride. In some embodiments, the first polymer precursor is pyromellitic dianhydride, the second polymer precursor is 1,6-diaminohexane and the modifying agent is aniline. In some embodiments, the first polymer precursor is pyromellitic dianhydride, the second polymer precursor is 1,6-diaminohexane and the modifying agent is selected from a group consisting of formic acid and acetic acid.

### Deposition of Organic Polymer Comprising Polyimide

The methods disclosed herein may be vapor deposition processes. In other words, the precursors for deposition are provided into the reaction chamber in a vapor phase.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

Material comprising polyimide, such as a polyimide-comprising layer, may be deposited by providing an acetic anhydride and a diamine, such as pyromellitic anhydride and 1,6-diaminohexane into the reaction chamber. In some embodiments, the process is a cyclic deposition method. Thus, in some embodiments, providing the first polymer precursor and the second polymer precursor into the reaction chamber is repeated. In some embodiments, providing a first polymer precursor and providing the second polymer precursor into the reaction chamber are repeated at least once. A polyimide-comprising layer of desired thickness may be deposited by a cyclic deposition process. In some embodiments, providing the first polymer precursor and the second polymer precursor is repeated at least five times. In some embodiments, providing the first polymer precursor and the second polymer precursor is repeated at least ten times. In some embodiments, providing the first polymer precursor and the second polymer precursor is repeated at least 20 times. In some embodiments, providing the first polymer precursor and the second polymer precursor is repeated at least 50 times. In some embodiments, the first polymer precursor and the second polymer precursor are provided alternately and sequentially into a reaction chamber to an organic polymer comprising polyimide. In some embodiments, the method according to the current disclosure is a cyclic deposition method and comprises providing the first polymer precursor and the second polymer precursor into the reaction chamber alternately and sequentially. The reaction chamber may be purged between two precursor pulses.

In some embodiments the substrate is held at a temperature of greater than about 80° C. during at least one deposition cycle. In some embodiments the substrate is held at a temperature of greater than about 100° C. during at least one deposition cycle. In some embodiments the substrate is held at a temperature of greater than about 120° C. during at least one deposition cycle. In some embodiments the substrate is held at a temperature of greater than about 150° C. during at least one deposition cycle. In some embodiments the substrate is held at a temperature of greater than about 170° C. during at least one deposition cycle. In some embodiments the substrate is held at a temperature of greater than about 200° C. during at least one deposition cycle. In some embodiments the substrate is held at a temperature of greater than about 250° C. during at least one deposition cycle. In some embodiments the substrate is held at a temperature of greater than about 300° C. during at least one deposition cycle. In some embodiments the substrate is held at a temperature of greater than about 350° C. during at least one deposition cycle. In some embodiments, the temperature in the reaction chamber is substantially the same throughout the deposition process. In some embodiments the substrate is held at a temperature of greater than about 80° C. or about 100° C. or about 120° C. or about 150° C. or about 170° C. or about 200° C. or about 250° C. or about 300° C. or about 350° C. during the one or more deposition cycles.

In some embodiments, organic polymer comprising polyimide may be deposited at a temperature from about 150° C. to about 450° C. For example, organic polymer comprising polyimide may be deposited at a temperature from about 200° C. to about 400° C., or at a temperature from about 250° C. to about 350° C., or at a temperature from about 300° C. to about 375° C. The modifying agent may be provided into the reaction chamber at the same temperature as the organic polymer comprising polyimide is deposited. Alternatively, the temperature during providing the modifying agent into the reaction chamber is different from the temperature at which the organic polymer comprising polyimide is deposited. In some embodiments, the substrate is heated before providing the modifying agent into the reaction chamber. In some embodiments, the temperature of the reaction chamber during providing the modifying agent into the reaction chamber is from about 200° C. to about 450° C.

In some embodiments, the organic polymer comprising polyimide is deposited at a first temperature. The first temperature may be, below about 200° C., such as from about 170° C. to about 190° C. The modifying agent may be deposited at the first temperature or at a second temperature. The second temperature may be higher than the first temperature. For example, the second temperature may be from about 200° C. to about 500° C. In some embodiments, the second temperature is from about 200° C. to about 450° C., or from about 200° C. to about 350° C., or from about 200° C. to about 300° C., or from about 250° C. to about 400° C.

In some embodiments, the deposition of an organic polymer comprising polyimide comprises a cyclic deposition process. The cyclic deposition process according to the current disclosure may be termed molecular layer deposition. The term “cyclic deposition process” can refer to the sequential introduction of precursor(s) and/or reactant(s) into a reaction chamber to deposit material, such as an organic polymer comprising polyimide, on a substrate. The process may comprise a purge step between providing precursors or between providing a precursor and a reactant in the reaction chamber.

The process may comprise one or more cyclic phases. In some embodiments, the process comprises or one or more acyclic phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first polymer precursor into the reaction chamber. In some embodiments, the cyclic deposition process comprises purging the reaction chamber after providing a second polymer precursor into the reaction chamber. In some embodiments, the cyclic deposition process comprises purging the reaction chamber after providing a first polymer precursor into the reaction chamber, and after providing second polymer precursor into the reaction chamber and providing a modifying reactant into the reaction chamber. Without limiting the current disclosure to any specific theory, ALD and MILD may be similar processes in terms of self-limiting reactions and slower and more controllable layer growth speed compared to CVD. Generally, ALD is used to deposit inorganic materials, whereas in MILD, the precursors may be fully organic molecules.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

The reaction chamber can form part of an atomic layer deposition (ALD) assembly. The reaction chamber can form part of a chemical vapor deposition (CVD) assembly. The deposition assembly may be an ALD or a CVD deposition assembly, but in certain process steps, such as in the deposition of a modified organic polymer according to the current disclosure, MILD may also be employed in some parts of the deposition process flows. The assembly may be a single wafer reactor. Alternatively, the reactor may be a batch reactor. The assembly may comprise one or more multi-station deposition chambers. Various phases of method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The material comprising an organic polymer according to the current disclosure may be deposited in a cross-flow reaction chamber. The material comprising an organic polymer according to the current disclosure may be deposited in a showerhead-type reaction chamber.

In some embodiments, the first polymer precursor, the second polymer precursor and the modifying agent are all provided into the reaction chamber during one deposition cycle. Thus, a deposition process comprises at least one deposition cycle in which the first polymer precursor, the second polymer precursor and the modifying agent are provided into the reaction chamber. In some embodiments, substantially all the deposition cycles of a deposition process comprise providing the polymer precursor, the second polymer precursor and the modifying agent into the reaction chamber. Such deposition schemes may be denoted “ABC” deposition schemes, wherein A denotes providing a first polymer precursor into the reaction chamber, B denotes providing the second polymer precursor into the reaction chamber and C denotes providing modifying agent into the reaction chamber. The reaction chamber may be purged after providing the first polymer precursor, the second polymer precursor and/or the modifying agent into the reaction chamber. The ABC deposition cycle may be repeated a predetermined number of times to achieve desired thickness of material comprising an organic polymer [n(A+B+C)], wherein n is the number of deposition cycles. For example, n may be from 1 to about 1,000, or from about 5 to about 1,000, or from about 10 to about 1,000, or from about 100 to about 1,000. In some embodiments, n is from about 3 to about 500, or from about 5 to about 500, or from about 10 to about 500, or from about 50 to about 500. In some embodiments, n is from about 50 to about 300, or from about 10 to about 200, or from about 200 to about 600. The number of repetitions of the deposition cycle depends on the per-cycle growth rate (GPC) of the material comprising an organic polymer and of the desired thickness of the material. The modifying agent may be provided to the reaction chamber holding the substrate in a single pulse or in a sequence of multiple pulses. In some embodiments, the modifying agent is provided in a single long pulse. In some embodiments, the modifying agent is provided in multiple shorter pulses, such as from 2 to about 30 pulses. The pulses may be provided sequentially. There may be a purge between two consecutive modifying agent pulses. The first polymer precursor may be provided to the reaction chamber holding the substrate in a single pulse or in a sequence of multiple pulses. In some embodiments, the first polymer precursor is provided in a single long pulse. In some embodiments, the first polymer precursor is provided in multiple shorter pulses, such as from 2 to about 30 pulses. The second polymer precursor may be provided to the reaction chamber holding the substrate in a single pulse or in a sequence of multiple pulses. In some embodiments, the second polymer precursor is provided in a single long pulse. In some embodiments, the second polymer precursor is provided in multiple shorter pulses, such as from 2 to about 30 pulses. For example, a master cycle may comprise providing a first polymer precursor into the reaction chamber in a single pulse, then providing the second polymer precursor into the reaction chamber in multiple pulses, for example, in about 15 to about 25 pulses, and then providing a modifying agent into the reaction chamber in a single pulse. The pulses may be provided sequentially.

In some embodiments, a deposition process according to the current disclosure comprises at least one deposition cycle that does not contain providing the modifying agent into the reaction chamber. In some embodiments, providing the first polymer precursor and the second polymer precursor into the reaction chamber are repeated at least once before providing the modifying agent into the reaction chamber. Such embodiments may be described in short by a formula y(x(a+b)+c), wherein a denotes first polymer precursor pulse, b denotes second polymer precursor pulse, c denotes a modifying agent pulse, x denotes the times the first polymer precursor and the second polymer precursor are pulsed (i.e. deposition subcycle) before the modifying agent is provided into the reaction chamber, and y denotes the number of times the whole process (i.e. master cycle) is performed. In some embodiments, the method is a cyclic deposition method and comprises providing the first polymer precursor and the second polymer precursor into the reaction chamber at least twice before providing the modifying agent into the reaction chamber. In some embodiments, the first polymer precursor and the second polymer precursor are provided into the reaction chamber at least five times before providing the modifying agent into the reaction chamber. In some embodiments, the first polymer precursor and the second polymer precursor are provided into the reaction chamber at most five times before providing the modifying agent into the reaction chamber.

In embodiments described by the formula above, providing different precursors and reactants in the reaction chamber take place in discrete pulses. The process may or may not comprise purge between pulses. However, in some embodiments, providing the first polymer precursor and the second polymer precursor into the reaction chamber may at least partially overlap or at least one of the precursors may be provided into the reaction chamber continuously. In such embodiments, it is possible to continue supplying the precursors into the reaction chamber for a predetermined time before providing the modifying agent into the reaction chamber.

In some embodiments, the first polymer precursor and the second polymer precursor are co-pulsed, i.e. the two precursors are provided at least partially simultaneously into the reaction chamber. In some embodiments, the pulses of the first polymer precursor and the second polymer precursor overlap partially. In some embodiments, the pulses of the first polymer precursor and the second polymer precursor overlap completely.

A deposition process may be any combination of above deposition schemes.

In some embodiments, the organic polymer comprising polyimide is deposited by fist cyclically depositing an as-deposited organic polymer comprising polyimide on the substrate, and subsequently, a modifying agent is provided into the reaction chamber to modify the as-deposited organic polymer comprising polyimide. In some embodiments, the modifying agent is provided into the reaction chamber after the as-deposited organic polymer comprising polyimide of desired thickness has been deposited. In some embodiments, the modifying agent is provided into the reaction chamber before the deposition of the as-deposited organic polymer comprising polyimide has been fully deposited. The selected time of modification depends on the modifying agent used. For example, in case of a modifying agent such as aniline, the modifying agent may modify the organic polymer by passivating the as-deposited organic polymer against further polymer growth by occupying active sites available for further polymer growth. In such embodiments, the modifying agent may be provided after the organic material comprising polyimide has been fully deposited.

### Purging

As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a catalyst and a precursor. Purging may avoid, or at least reduce, gas-phase interactions between the two gases reacting with each other. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a material is deposited does not move. For example in the case of spatial purges, a purge step can take the following form: moving a substrate from a first location to which a first precursor is continually supplied, through a purge gas curtain or another type of a hindrance to gas movement between locations, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

### Thermal Process

In some embodiments, the deposition process, such as a cyclic deposition process, according to the current disclosure comprises a thermal deposition process. In thermal deposition, the chemical reactions are promoted by increased temperature relevant to ambient temperature. Generally, temperature increase provides the energy needed for the deposition and/or forming of an organic polymer comprising polyimide in the absence of other external energy sources, such as plasma, radicals, or other forms of radiation. In some embodiments, the vapor deposition process according to the current disclosure is a thermal MILD process. A thermal process may be preferred in selective vapor deposition processes over plasma-enhanced processes since plasma exposure may damage the passivation layer or alter its inhibition properties. However, one or more plasmas may be utilized in other process phases, such as etching away unwanted materials.

### Pressure

The methods according to the current disclosure may be performed in reduced pressure relative to the ambient pressure. In some embodiments, a pressure within the reaction chamber during the deposition process according to the current disclosure is less than 500 Torr, or a pressure within the reaction chamber during the deposition process is between 0.01 Torr and 500 Torr, or between 0.01 Torr and 100 Torr, or between 0.01 Torr and 10 Torr. In some embodiments, a pressure within the reaction chamber during the deposition process is less than about 10 Torr, less than about 50 Torr, less than about 100 Torr or less than about 300 Torr. In some embodiments, the pressure of the reaction chamber is between about 2 Torr and about 8 Torr during the deposition process. For example, the pressure during the deposition process may be about 1 Torr, about 4 Torr or about 6 Torr. In some embodiments, the pressure in the reaction chamber during providing the modifying agent into the reaction chamber is below about 100 Torr, or below 50 about Torr, or below 10 about Torr, or below 5 about Torr.

A pressure in a reaction chamber may be selected independently for different process steps. In some embodiments, a substantially constant or a constant pressures is used during a deposition process. In some embodiments, at least two different pressures are used during a deposition cycle. In some embodiments, a first pressure is used during depositing organic polymer comprising polyimide and a second pressure is used during providing the modifying agent into the reaction chamber.

### As-Deposited Organic Polymer Comprising Polyimide

The first polymer precursor and the second polymer precursor react with each other to deposit an as-deposited organic polymer comprising polyimide on the substrate. The as-deposited organic polymer may comprise polyimide and polyamic acid. The as-deposited organic polymer may comprise further polymer types, such as polyamide. The proportion of polyamic acid to polyimide depends on the deposition conditions, and also on the properties of the substrate surface. Some substrate surfaces, such as silicon-containing surfaces, for example silicon oxide, such as SiO₂, and SiOC, favor the formation of polyimide, whereas some other substrate surface materials, such as metals, for example Cu, favor the formation of polyamic acid. Without limiting the current disclosure to any specific theory, polyimide may be preferred in some applications.

In some embodiments, the as-deposited organic polymer comprising polyimide (i.e. deposited organic polymer comprising polyimide) comprises at least 50 at-% or at least 75 at-% or at least 80 at-% polyamic acid. In some embodiments, the ratio of polyamic acid to polyimide in the organic polymer is reduced from about 4:1 or from about 3:1 to about 2:1 or to about 1:2 or to about 1:5 or to about 1:10 or to about 1:20 or to about 1:40 or less by modifying the as-deposited organic material comprising polyimide with a modifying agent according to the current disclosure. In some embodiments, polyamic acid is substantially removed from the as-deposited organic polymer comprising polyimide. In some embodiments, modified organic polymer formed by the methods disclosed herein is polymerized substantially only through polyimide bonds. In some embodiments, modified organic polymer formed by the methods disclosed herein is polymerized at least 50% through polyimide bonds. In some embodiments, modified organic polymer formed by the methods disclosed herein is polymerized at least 80% through polyimide bonds. In some embodiments, modified organic polymer formed by the methods disclosed herein is polymerized at least 90% through polyimide bonds. In some embodiments, modified organic polymer formed by the methods disclosed herein is polymerized at least 95% through polyimide bonds.

In some embodiments, the first polymer precursor and the second polymer precursor react with each other on the substrate surface. In some embodiments, the first polymer precursor and the second polymer precursor react with each other substantially only on the substrate surface.

In some embodiments, a layer comprising an organic polymer comprising polyimide (a polyimide-comprising layer) is deposited. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

In some embodiments, the polyimide-comprising layer is substantially continuous. In some embodiments, the polyimide-comprising layer is continuous. In some embodiments, the polyimide-comprising layer is substantially pinhole-free. In some embodiments, the polyimide-comprising layer is pinhole-free. In some embodiments, the polyimide-comprising layer has an approximate thickness of at least about 1 nm. In some embodiments, the polyimide-comprising layer has an approximate thickness of at least about 5 nm. In some embodiments, the polyimide-comprising layer has an approximate thickness of at least about 10 nm. In some embodiments, the polyimide-comprising layer has an approximate thickness of about 10 nm at maximum. In some embodiments, the polyimide-comprising layer has an approximate thickness from about 1 nm to about 10 nm. In some embodiments, substantially or completely continuous polyimide-comprising layer having a thickness of less than 10 nm, such as from about 4 nm to about 8 nm, for example about 5 nm or about 6 nm may be deposited on the substrate.

In some embodiments, the wet etch rate of the modified organic polymer comprising polyimide according to the current disclosure is from less than about 0.01 to about 0.1 nm/s, or from less than about 0.01 to about 0.05 nm/s, as measured by exposure to 0.5% HF. In some embodiments, the wet etch rate of the modified organic polymer is less than about 0.03 nm/s, or less than about 0.05 nm/s, or less than about 0.1 nm/s as measured by exposure to 0.5% HF.

In one aspect, an organic polymer layer comprising polyimide produced by the methods described herein is disclosed. In some embodiments, the organic polymer layer according to the current disclosure is substantially polyamic acid-free. In many applications, such as selective deposition, selective etching and patterning, substantially or completely pin-hole free layers may be used. It may be possible to deposit thin, such as less than 3 nm thick layers of organic polymer comprising polyimide by the methods disclosed herein that are substantially or completely pinhole-free. In some embodiments, a substantially polyamic acid free organic polymer layer comprising polyimide having a thickness of less than about 15 nm, or less than about 10 nm or less than about 5 nm or less than about 3 nm is disclosed.

In another aspect, a method of reducing polyamic acid content of an organic polymer comprising polyimide and polyamic acid is disclosed. The method comprises heating the organic polymer, such as as-deposited organic polymer, to a temperature of at least 170° C., such as to about 225° C. and contacting the organic polymer with a vapor-phase modifying agent comprising a hydroxyl group or a carbonyl group to imidize polyamic acid into polyimide. In some embodiments, the modifying agent comprises at least one hydroxyl group. In some embodiments, the modifying agent comprises at least one carbonyl group. In some embodiments, the modifying agent comprises at least one carboxylic acid group. In some embodiments, the temperature during contacting the as-deposited organic polymer comprising polyimide with a vapor-phase modifying agent is at most about 450° C. In some embodiments, the temperature during contacting the as-deposited organic polymer comprising polyimide with a vapor-phase modifying agent is at most about 350° C. In some embodiments, the temperature during contacting the as-deposited organic polymer comprising polyimide with a vapor-phase modifying agent is at most about 300° C. In some embodiments, the temperature during contacting the as-deposited organic polymer comprising polyimide with a vapor-phase modifying agent is at most about 250° C. In some embodiments, the temperature during contacting the as-deposited organic polymer comprising polyimide with a vapor-phase modifying agent is at most about 230° C., such as about 225° C. In some embodiments, the as-deposited organic polymer is a vapor-deposited layer on a semiconductor substrate.

In a further aspect, a method of forming a layer of organic polymer comprising polyimide on a surface of a semiconductor substrate is disclosed. The method comprises providing the semiconductor substrate in a reaction chamber, providing a first polymer precursor into the reaction chamber in a vapor phase, providing a second polymer precursor into the reaction chamber in a vapor phase to deposit an organic polymer comprising polyimide on the substrate. The first polymer precursor comprises a molecule having at least two acid anhydride groups and the second polymer precursor comprises a molecule comprising at least two amine groups. The method further comprises providing a modifying agent into the reaction chamber in a vapor phase to increase the proportion of polyimide in the as-deposited organic polymer formed on the substrate.

The methods disclosed herein may be useful in the manufacture of semiconductor devices. For example, in selective deposition processes, a polyimide layer may be used as passivation layer to direct the deposition of a material to the non-passivated materials surfaces. Correspondingly, in a yet another aspect, a method of fabricating a semiconductor device is disclosed. The method comprises forming a layer of organic polymer comprising polyimide on a surface of a semiconductor substrate according to the current disclosure.

Further, the current disclosure relates to a semiconductor processing assembly for processing a substrate. The processing assembly according to the current disclosure comprises a reaction chamber constructed and arranged to hold a substrate, a reactant source constructed and arranged to contain and evaporate a modifying agent comprising a carbonyl group or a hydroxyl group, a temperature control system constructed and arranged to regulate the temperature in the reaction chamber to be between 200° C. and 450° and a reactant injection system constructed and arranged to provide the modifying agent into the reaction chamber. In some embodiments, the semiconductor processing assembly further comprises a first polymer precursor source and a second polymer precursor source constructed and arranged to contain and evaporate a first polymer precursor and a second polymer precursor, respectively, and the reactant injector system is constructed and arranged to provide the first polymer precursor and the second polymer precursor into the reaction chamber to deposit an organic polymer comprising polyimide on the substrate.

### Selective Deposition—First Surface and Second Surface

In one aspect, a method of selectively depositing a target material on a first surface of a semiconductor substrate relative to a second surface of the same substrate is disclosed. In the method, the first surface and the second surface have different material properties, and the second surface comprises a layer of modified organic polymer comprising polyimide formed according to the current disclosure.

According to some aspects of the present disclosure, a target material, such as a layer, is deposited on a first surface of a semiconductor substrate relative to a second surface of the same substrate. The two surfaces have different material properties, and the second surface comprises a layer of modified organic polymer comprising polyimide formed according to the current disclosure.

In some embodiments, the first surface is a dielectric surface. In some embodiments, the first surface is a low-k surface. In some embodiments, the first surface comprises an oxide. In some embodiments, the first surface comprises a nitride. In some embodiments, the first surface comprises silicon. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride.

In some embodiments, the dielectric material comprises a metal oxide. Thus, in some embodiments, a target material is selectively deposited on a first metal oxide surface relative to a second surface. In some embodiments, the first surface is a high-k surface, such as hafnium oxide-comprising surface, a lanthanum oxide-comprising surface.

In some embodiments, a target material is selectively deposited on a first surface comprising a metal oxide relative to another surface. A metal oxide surface may be, for example a tungsten oxide surface, hafnium oxide (such as HfO₂) surface, titanium oxide (such as TiO₂ or Ti₂O₃) surface, aluminum oxide (such as Al₂O₃) surface or zirconium oxide (such as ZrO₂) surface. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, a target material, such as silicon nitride, silicon oxynitride or silicon carbonitride or a combination thereof, is selectively deposited on a first dielectric surface of a substrate relative to a second conductive (e.g., metal or metallic) surface of the substrate. In some embodiments the dielectric surface and metal or metallic surface are adjacent to each other. In some embodiments the dielectric surface material comprises a low k material. As described above, the second surface comprises modified organic polymer comprising polyimide according to the current disclosure. The organic polymer comprising polyimide may be selectively vapor-deposited on the second surface. The modified organic polymer comprising polyimide can function as a passivation layer. In such embodiments, forming the modified organic polymer comprising polyimide through the modifying agent disclosed herein may improve the passivation properties of the passivation layer. Without limiting the current disclosure to any specific theory, the imidization of the polyamic acid contained in the as-deposited organic polymer may reduce the availability of reactive sites in the passivation layer. This, in turn, may reduce the nucleation of the deposited target material on the passivation layer and therefore improve the selectivity of the selective deposition process.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide, niobium carbide, niobium boride, nickel oxide, cobalt oxide, niobium oxide, tungsten carbonitride (WNCx), tantalum nitride, or titanium nitride.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

The particular implementations shown and described are illustrative of the invention are not intended to otherwise limit the scope of the aspects and implementations in any way. Indeed, for the sake of brevity, conventional manufacturing, connection, preparation, and other functional aspects of the methods and assemblies according to the current disclosure may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

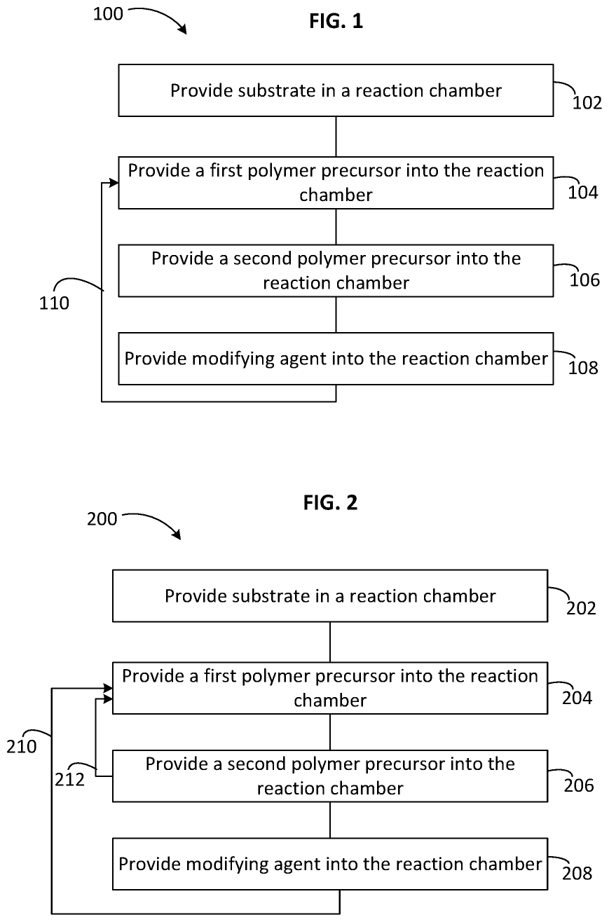

FIG. 1 depicts a block diagram of exemplary embodiments of a method according to the current disclosure. First, a substrate is provided in a reaction chamber at block 102. The substrate may comprise materials as described in the current disclosure. For example, in some embodiments, the substrate comprises a first surface and a second surface as described in the current disclosure. The substrate may be heated at block 102 prior to providing a first polymer precursor into the reaction chamber 104.

After providing the substrate into the reaction chamber, 102, a first polymer precursor is provided (such as pulsed) into the reaction chamber at block 204 to contact the first polymer precursor with the substrate. The first polymer precursor may be, for example, pyromellitic dianhydride. The first polymer precursor is provided into the reaction chamber in vapor phase. The first polymer precursor may be chemisorbed on the surface of the substrate. The duration of providing the first polymer precursor may be, for example from about 0.1 seconds to about 20 seconds, such as from about 3 seconds to about 15 seconds. For example, the duration of providing the first polymer precursor may be, about 1 second, about 2 seconds, about 5 seconds, about 10 seconds or about 15 seconds. The reaction chamber may be purged after providing the first polymer precursor into the reaction chamber. Purging is not indicated in FIG. 1, but it may be optionally included in block 104.

At block 106, a second polymer precursor is provided into the reaction chamber in a vapor phase. In an exemplary embodiment, the second polymer precursor is 1,6-diaminohexane. The second polymer precursor reacts with the chemisorbed first polymer precursor to form as-deposited material comprising an organic polymer on the first surface of the substrate. This material is as-deposited organic polymer and may comprise additional polymers in addition to polyimide, such as polyamic acid. The second polymer precursor may be provided into the reaction chamber (such as pulsed) for about 1 to 15 seconds, for example, about 1 second, about 1.5 seconds, about 2 seconds, about 3 seconds, about 5 seconds or about 8 seconds. The reaction chamber may be purged after a second polymer precursor pulse. Purging is not indicated in FIG. 1, but it may be optionally included in block 106.

Although not depicted separately in the drawing, in some embodiments, it may be advantageous to start the process by providing the second polymer precursor into the reaction chamber first.

At block 108, a modifying agent is provided into the reaction chamber in a vapor phase. In an exemplary embodiment, the modifying agent is acetic anhydride or acetic acid. The modifying agent reacts with the formed as-deposited organic polymer comprising polyimide to form an organic polymer comprising polyimide that has a higher polyimide content that the as-deposited organic polymer comprising polyimide. The reaction chamber may be purged after a modifying agent pulse. Purging is not indicated in FIG. 1, but it may be optionally included in block 108.

The deposition process according to the current disclosure may be a cyclic deposition process. Thus, at loop 110, the deposition cycle is initiated again. The deposition cycle may be repeated as many times as needed to deposit a desired amount of an organic polymer comprising polyimide on the substrate. For example, the deposition cycle may be performed from 2 to about 800 times, or from about 10 to about 500 times, or from about 10 to about 500 times, or from about 50 to 300 times. For example, the deposition cycle may be performed about 70 times, about 100 times, about 150 times, about 200 times or about 400 times. Although not depicted in the current disclosure, the process may comprise additional steps, for example intermittent plasma treatments or heating. The substrate may be heat treated in addition to treating it with the modifying agent. The increase in polyimide content may be synergistic when both treatments are combined, although heating alone may not be feasible in many applications due to limitations in thermal budget and material migration during an extended heat treatment.

Although not depicted in the drawings block diagrams, it is possible for the phases of the deposition process to overlap. For example, phases 104 and 106 may be performed at least partially simultaneously. In some embodiments, phases 106 and 108 are performed at least partially simultaneously.

FIG. 2 is a block diagram of additional exemplary embodiments of a method according to the current disclosure. Blocks 202, 204, 206 and 208 are performed similarly to the embodiments described in FIG. 1. In the embodiments of FIG. 2, blocks 204 and 206 form a polymer deposition subcycle that is performed at least 2 times (loop 212) before the master cycle, comprising also block 208, and indicated by loop 210, is repeated. The number of repetitions of the polymer deposition subcycle 212 may vary, and the ratio of repeats of loop 212 to a loop 210 may be selected based on optimizing the process in question. Thus, the number of organic polymer deposition subcycles 212 to be performed in each master cycle 210 may vary. For example, the polymer deposition subcycle can be performed at least twice in each master cycle. In some embodiments, the polymer deposition subcycle is performed from 2 to about 50 times, for example about 10 or about 20 or about 30 times, in each master cycle.

It is explicitly disclosed that, in some embodiments, the modifying agent is provided into the reaction only once at the end of the deposition process. In such embodiments, the number of loops 210 is 0. Such embodiment may be advantageous if the organic polymer layer is sufficiently thin for the modifying agent to reach sufficient large portion of the deposited material. Further, embodiments can be envisaged in which it is enough that only the surface of the deposited polymer material is modified.

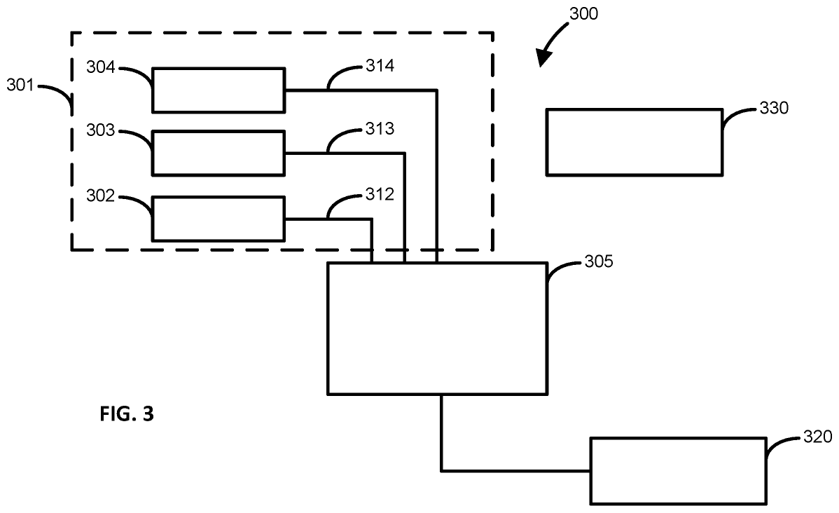

FIG. 3 illustrates a semiconductor processing assembly 300 according to the current disclosure in a schematic manner. In one aspect, a semiconductor processing assembly for processing a substrate is disclosed. The semiconductor substrate processing assembly 300 comprises one or more reaction chambers 305 constructed and arranged to hold the substrate, a precursor injector system 301 constructed and arranged to provide a first polymer precursor, a second polymer precursor and a modifying agent into the reaction chamber in a vapor phase. The processing assembly 300 comprises a first reactant vessel 302 constructed and arranged to contain the first polymer precursor, a second reactant vessel 303 constructed and arranged to contain the second polymer precursor, and a third reactant vessel 304 constructed and arranged to contain the modifying agent. The assembly is constructed and arranged to provide the first polymer precursor and the second polymer precursor via the precursor injector system 301 into the reaction chamber 305 to deposit an as-deposited organic polymer comprising polyimide on the substrate. The assembly is further constructed and arranged to provide the modifying agent via the precursor injector system 301 into the reaction chamber 305 to form an organic polymer comprising polyimide on the substrate.

Processing assembly 300 can be used to perform a method as described herein. In addition to the above-mentioned one or more reaction chambers 305, a precursor injector system 301, a first reactant vessel 302, a second reactant vessel 303, a third reactant vessel 304, the processing assembly 300 includes an exhaust source 320, and a controller 330. The processing assembly 300 may comprise one or more additional gas sources (not shown), such as an inert gas source, a carrier gas source and/or a purge gas source. In embodiments, in which further processing of the substrate, such as selective deposition, is performed in the same processing assembly 300, the processing assembly 300 may comprise the corresponding further sources and associated components. In some embodiments, a method according to the current disclosure is performed in a reaction chamber of a cluster tool, whereas further processing of the substrate may take place in other reaction chambers of the same cluster tool. The processing assembly 300 can include any suitable reaction chamber, such as an ALD or CVD reaction chamber in addition to a reaction chamber configured and arranged for MLD.

The first reactant vessel 302 can include a vessel and a first polymer precursor as described herein—alone or mixed with one or more carrier (e.g., inert) gases. A second reactant vessel 303 can include a vessel and a second polymer precursor as described herein—alone or mixed with one or more carrier gases. A third reactant vessel 304 can include a modifying agent as described herein. Although illustrated with three source vessels 302-304, processing assembly 300 can include any suitable number of source vessels. Source vessels 302-304 can be coupled to reaction chamber 305 via lines 312-314, which can each include flow controllers, valves, heaters, and the like. In some embodiments, each of the first polymer precursor in the first reactant vessel 302, the second polymer precursor in the second reactant vessel 303 and/or the modifying agent in the third reactant vessel 304 may be independently heated or kept at ambient temperature. In some embodiments, a vessel is heated so that a precursor or a reactant reaches a suitable temperature for vaporization

Exhaust source 320 can include one or more vacuum pumps.

Controller 330 includes electronic circuitry and software to selectively operate valves, manifolds, heaters, pumps and other components included in the processing assembly 300. Such circuitry and components operate to introduce precursors, reactants and purge gases from the respective sources. Controller 330 can control timing of gas pulse sequences, temperature of the substrate and/or reaction chamber 305, pressure within the reaction chamber 305, and various other operations to provide proper operation of the processing assembly 300. Controller 330 can include control software to electrically or pneumatically control valves to control flow of precursors, reactants and purge gases into and out of the reaction chamber 305. Controller 330 can include modules such as a software or hardware component, which performs certain tasks. A module may be configured to reside on the addressable storage medium of the control system and be configured to execute one or more processes.

Other configurations of processing assembly 300 are possible, including different numbers and kinds of precursor and reactant sources. For example, a reaction chamber 305 may comprise more than one, such as two or four, deposition stations. Such a multi-station configuration may have advantages if, for example, forming an organic polymer and subsequent substrate processing are performed in the same reaction chamber. Further, it will be appreciated that there are many arrangements of valves, conduits, precursor sources, and reactant sources that may be used to accomplish the goal of selectively and in coordinated manner feeding gases into reaction chamber 305. Further, as a schematic representation of a processing assembly, many components have been omitted for simplicity of illustration, and such components may include, for example, various valves, manifolds, purifiers, heaters, containers, vents, and/or bypasses.

During operation of processing assembly 300, substrates, such as semiconductor wafers (not illustrated), are transferred from, e.g., a substrate handling system to reaction chamber 305. Once substrate(s) are transferred to reaction chamber 305, one or more gases from gas sources, such as precursors, reactants, carrier gases, and/or purge gases, are introduced into reaction chamber 305.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

In some embodiments, the substrate may be pretreated or cleaned prior to or at the beginning of the method according to the current disclosure. In some embodiments, the substrate may be subjected to a plasma cleaning process at prior to or at the beginning of the method according to the current disclosure. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the method according to the current disclosure. In some embodiments, the substrate surface may be exposed to hydrogen plasma, radicals, or atomic species. In some embodiments, a pretreatment or cleaning process may be carried out in the same reaction chamber as a method according to the current disclosure. However, in some embodiments, a pretreatment or cleaning process may be carried out in a separate reaction chamber.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various methods and assemblies, and other features, functions, acts, and/or properties disclosed herein, as well as any and all equivalents thereof.

1. A method of forming a modified organic polymer comprising polyimide, the method comprising:
providing a substrate in a reaction chamber;
providing a first polymer precursor into the reaction chamber in a vapor phase; and
providing a second polymer precursor into the reaction chamber in a vapor phase to deposit an organic polymer comprising polyimide on the substrate;
wherein the first polymer precursor comprises a molecule having at least two acid anhydride groups and the second polymer precursor comprises a molecule comprising at least two amine groups, and
wherein the method further comprises providing a modifying agent into the reaction chamber in a vapor phase to increase the proportion of polyimide in the organic polymer on the substrate to form the modified organic polymer comprising polyimide.

2. The method of claim 1, wherein the providing a first polymer precursor and the providing the second polymer precursor into the reaction chamber are repeated at least once.

3. The method of claim 1, wherein providing the first polymer precursor and the second polymer precursor into the reaction chamber are repeated at least once before providing the modifying agent into the reaction chamber.

4. The method of claim 1, wherein the molecule comprising at least two acid anhydride groups is pyromellitic dianhydride.

5. The method of claim 1, wherein the molecule comprising at least two amine groups comprises at least one primary amine.

6. The method of claim 1, wherein the molecule comprising at least two amine groups is selected from a group consisting of 4,4′-oxydianiline, 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine, 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 1,6-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene, 1,4-diaminobenzene, decane-1,10-diamine, and 4-nitrobenzene-1,3-diamine.

7. The method of claim 1, wherein the modifying agent is a dehydrating agent.

8. The method of claim 1, wherein the modifying agent is selected from the group consisting of carboxylic acids, acid anhydrides, and primary amines.

9. The method of claim 8, wherein the modifying agent comprises an aromatic ring.

10. The method of claim 8, wherein the modifying agent is selected from the group consisting of acetic acid, formic acid, benzoic acid, m-hydroxybenzoic acid, p-hydroxybenzoic acid, p-aminobenzoic acid, m-aminobenzoic acid, benzene-1,4-dicarboxylic acid, acetic anhydride, succinic anhydride, maleic anhydride, phthalic anhydride, aniline, 4-aminophenol, and quinolone.

11. The method of claim 1, wherein the method is a cyclic deposition method and comprises providing the first polymer precursor and the second polymer precursor into the reaction chamber alternately and sequentially.

12. The method of claim 1, wherein the method is a cyclic deposition method and comprises providing the first polymer precursor and the second polymer precursor into the reaction chamber at least twice before providing the modifying agent into the reaction chamber.

13. The method of claim 1, wherein the temperature of the reaction chamber during providing the modifying agent into the reaction chamber is from about 200° C. to about 450° C.

14. The method of claim 1, wherein the pressure of the reaction chamber is between about 2 Torr and about 8 Torr during providing the modifying agent into the reaction chamber.

15. The method of claim 1, wherein a ratio of polyamic acid to the polyimide in the as-deposited organic polymer is reduced from at least about 3:1 to less than about 1:30.

16. The method of claim 1, wherein polyamic acid is substantially removed from the modified organic polymer comprising polyimide.

17. A method of reducing polyamic acid content of an organic polymer comprising polyimide and polyamic acid, the method comprising:
heating an as-deposited organic polymer to a temperature of at least 170° C.; and contacting the as-deposited organic polymer with a vapor-phase modifying agent comprising a hydroxyl group or a carbonyl group to imidize polyamic acid into polyimide.

18. The method of claim 17, wherein the temperature is at most about 325° C.

19. The method of claim 17, wherein the as-deposited organic polymer is a vapor-deposited layer on a semiconductor substrate.

20. A semiconductor processing assembly for processing a substrate comprising a reaction chamber constructed and arranged to hold a substrate;
a reactant source constructed and arranged to contain and evaporate a modifying agent comprising a carbonyl group or a hydroxyl group;
a temperature control system constructed and arranged to regulate the temperature in the reaction chamber to be between 200° C. and 450°; and
a reactant injection system constructed and arranged to provide the modifying agent into the reaction chamber.
